(19) United States
(12) Patent Application Publication
(10) Pub. No.: US 2026/0202761 A1
(43) Pub. Date: Jul. 16, 2026

(54) METROLOGY SYSTEM BASED ON MULTIMODE OPTICAL FIBER IMAGING AND LITHOGRAPHIC APPARATUS

(71) Applicant: ASML NETHERLANDS B.V., Veldhoven (NL)

(72) Inventors: Aniruddha Ramakrishna SONDE, Stamford, CT (US); Mahesh Upendra AJGAONKAR, Guilford, CT (US); Krishanu SHOME, Cheshire, CT (US)

(73) Assignee: ASML NETHERLANDS B.V., Veldhoven (NL)

(21) Appl. No.: 19/133,142

(22) PCT Filed: Nov. 30, 2023
(86) PCT No.: PCT/EP2023/083793

§ 371 Date: May 27, 2025

Related U.S. Application Data
(60) Provisional application No. 63/435,707, filed on Dec. 28, 2022.

(51) Int. Cl. G03F 7/00

(52) U.S. Cl. CPC G03F 7/706851; G03F 7/70633; G03F 7/706837; G03F 7/706841; G03F 7/706845

(57) ABSTRACT

An inspection system includes a radiation source, a multimode optical fiber, an optical structure, a two-dimensional detector array, and a computing device. The radiation source irradiates a target to generate scattered radiation from the target. The scattered radiation includes a diffraction order pair. The multimode optical fiber receives the scattered radiation and outputs a mix of the diffraction order pair based on a propagation property of the multimode optical fiber. The optical structure combines the diffraction order pair at an input side of the multimode optical fiber. The two-dimensional detector array receives the mix of the diffraction order pair and generates a measurement signal corresponding to the mix of the diffraction order pair. The computing device analyzes the measurement signal based on the propagation property and discriminates intensities of the diffraction order pair based on the analyzing.

### CROSS-REFERENCE TO RELATED APPLICATION

This application claims priority of a U.S. application Ser. No. 63/435,707 which was filed on 28 Dec. 2022 and which is incorporated herein in its entirety by reference.

### FIELD

The present disclosure relates to metrology systems, for example, an inspection system for measuring mark asymmetry in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which can be a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (photoresist or simply “resist”) provided on the substrate. In general, a single substrate will contain a network of adjacent target portions that are successively patterned. Known lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”—direction) while synchronously scanning the target portions parallel or anti-parallel to this scanning direction. It is also possible to transfer the pattern from the patterning device to the substrate by imprinting the pattern onto the substrate.

During lithographic operation, different processing steps can entail different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic apparatus can use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters can include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

The printing accuracy of a lithographic system can rely heavily on the precision of the inspection tools it uses.

### SUMMARY

Accordingly, it is desirable to improve metrology techniques for higher measurement accuracy. For example, optical inspection processes can be performed more precisely based on the devices and methods disclosed herein.

In some aspects, an inspection system can comprise a radiation source, a multimode optical fiber, an optical structure, a two-dimensional detector array, and a computing device. The radiation source can be configured to irradiate a target to generate scattered radiation. The scattered radiation can comprise a diffraction order pair. The multimode optical fiber can be configured to receive the scattered radiation and to output a mix of the diffraction order pair based on a propagation property of the multimode optical fiber. The optical structure can be configured to combine the diffraction order pair at an input side of the multimode optical fiber. The two-dimensional detector array can be configured to receive the mix of the diffraction order pair and to generate a measurement signal corresponding to the mix of the diffraction order pair. The computing device can be configured to analyze the measurement signal based on the propagation property and to discriminate intensities of the diffraction order pair based on the analyzing.

In some aspects, a lithographic apparatus can comprise an illumination system, a projection system, and an inspection system. The illumination system can be configured to illuminate a pattern of a patterning device. The projection system can be configured to project an image of the pattern onto a substrate. The inspection system can comprise a radiation source, a multimode optical fiber, an optical structure, a two-dimensional detector array, and a computing device. The radiation source can be configured to irradiate a target on the substrate to generate scattered radiation from the target. The scattered radiation can comprise a diffraction order pair. The multimode optical fiber can be configured to receive the scattered radiation and to output a mix of the diffraction order pair based on a propagation property of the multimode optical fiber. The optical structure can be configured to combine the diffraction order pair at an input side of the multimode optical fiber. The two-dimensional detector array can be configured to receive the mix of the diffraction order pair and to generate a measurement signal corresponding to the mix of the diffraction order pair. The computing device can be configured to analyze the measurement signal based on the propagation property and to discriminate intensities of the diffraction order pair based on the analyzing.

In some aspects, a method can comprise one or more of the following operations. The method can comprise generating scattered radiation comprising first and second diffracted beams by irradiating a lithography target. The method can further comprise splitting the scattered radiation to produce a first portion of the first diffracted beam, a first portion of the second diffracted beam, a second portion of the first diffracted beam, and a second portion of the second diffracted beam. The method can further comprise generating a first measurement signal based on the first portions being received at a first two-dimensional detector array. The method can further comprise receiving the second portions at an input side of a multimode optical fiber to mix the second portions of the first and second diffracted beams based on a propagation property of the multimode optical fiber. The method can further comprise generating a second measurement signal based on the mixed second portions being received at a second two-dimensional detector array. The method can further comprise quantifying the propagation property of the multimode optical fiber based on analyzing the first and second measurement signals to compare the first portions and the mixed second portions.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 2 shows more details of a reflective lithographic apparatus, according to some aspects.

FIG. 3 shows a lithographic cell, according to some aspects.

FIGS. 4A and 4B show inspection apparatuses, according to some aspects.

FIG. 5 shows a portion of an inspection apparatus 500, according to some aspects.

FIG. 6 shows a calibration system for calibrating a multimode optical fiber to be used in an inspection system, according to some aspects.

FIG. 7 shows a method for characterizing and using a transfer function of multimode optical fiber, according to some aspects.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

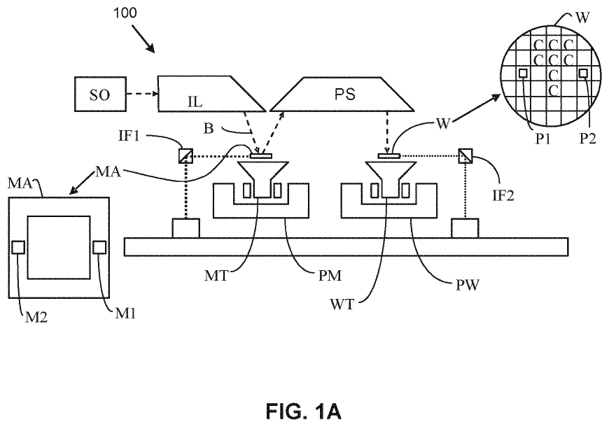

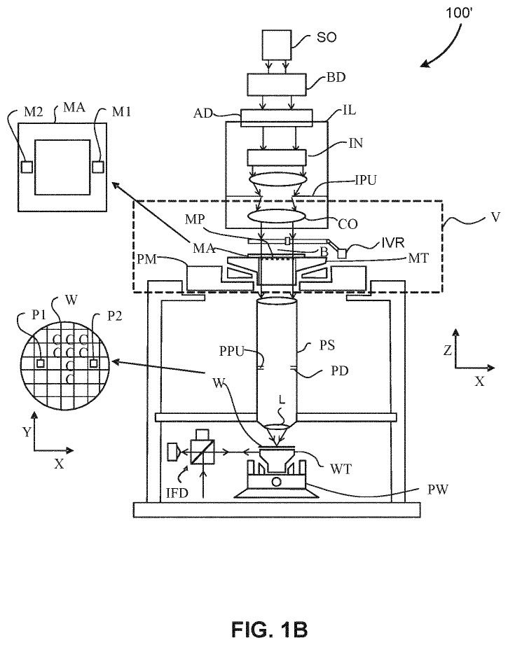

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mark pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-)magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some aspects, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

In some aspects, lithographic apparatus 100′ includes a deep ultraviolet (DUV) source, which is configured to generate a beam of DUV radiation for DUV lithography. In general, the DUV source is configured in a radiation system, and a corresponding illumination system is configured to condition the DUV radiation beam of the DUV source.

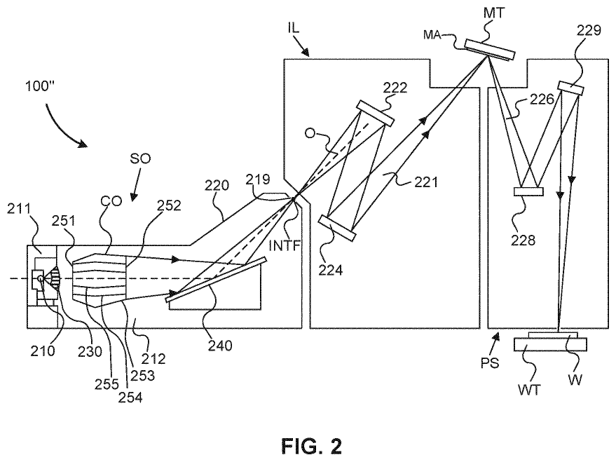

FIG. 2 shows the lithographic apparatus 100′ in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. EUV radiation can be produced by a gas or vapor, for example Xe gas, Li vapor, or Sn vapor in which EUV radiation emitting plasma 210 is created to emit radiation in the EUV range of the electromagnetic spectrum. The EUV radiation emitting plasma 210 is created by, for example, an electrical discharge causing at least a partially ionized plasma. Partial pressures of, for example, 10 Pa of Xe, Li, Sn vapor, or any other suitable gas or vapor can be used for efficient generation of the radiation. In some aspects, a plasma of excited tin (Sn) (e.g., excited via a laser) is provided to produce EUV radiation.

The radiation emitted by the EUV radiation emitting plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the EUV radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Example Lithographic Cell

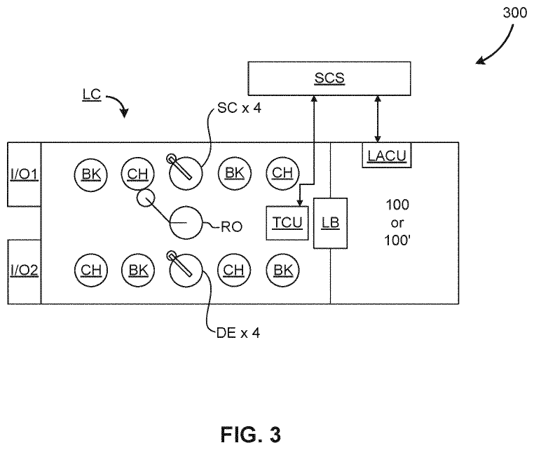

FIG. 3 shows a lithographic cell 300, also sometimes referred to a lithocell or cluster, according to some aspects. Lithographic apparatus 100 or 100′ can form part of lithographic cell 300. Lithographic cell 300 can also include one or more apparatuses to perform pre-and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

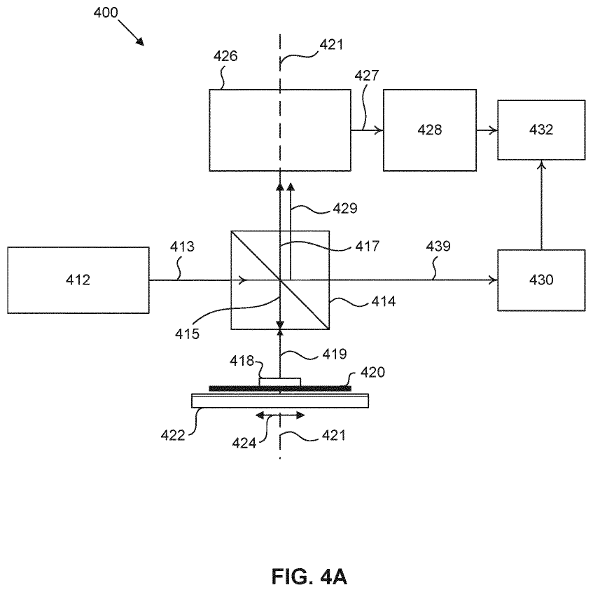

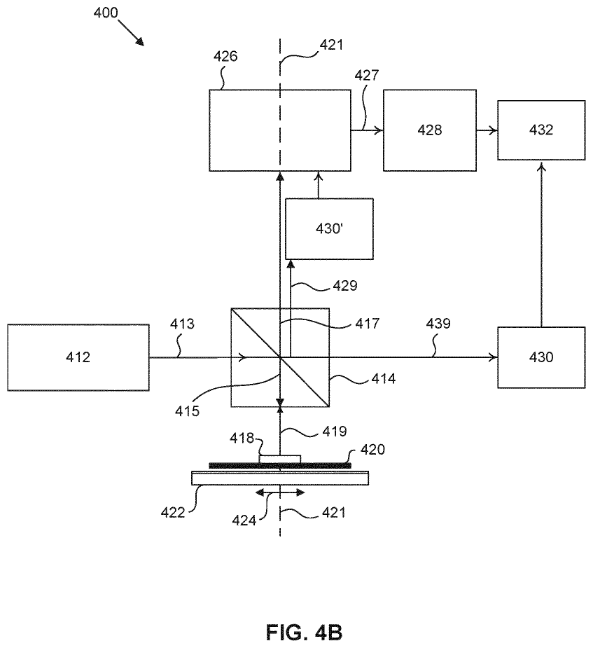

FIG. 4A shows a cross-sectional view of an inspection apparatus 400 that can be implemented as a part of lithographic apparatus 100 or 100′, according to some aspects. In some aspects, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

The terms “inspection apparatus,” “metrology system,” or the like can be used herein to refer to, e.g., a device used for measuring a property of a structure (e.g., overlay sensor, critical dimension sensor, or the like), a device or system used in a lithographic apparatus to inspect an alignment of a wafer (e.g., alignment sensor), or the like.

In some aspects, inspection apparatus 400 can include an illumination system 412, a beam splitter 414, an interferometer 426, a detector 428, a beam analyzer 430, and a calculation processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some aspects, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some aspects, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677(1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some aspects, beam splitter 414 can be further configured to receive diffraction radiation beam 419 and split diffraction radiation beam 419 into at least two radiation sub-beams, according to an aspect. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. Other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example aspect, diffracted radiation sub-beam 429 can be at least a portion of radiation sub-beam 415 that can be reflected from alignment mark or target 418. In an example of this aspect, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed. It can be enough to have the features of alignment mark 418 resolved. Interferometer 426 can be further configured to rotate one of the two images with respect to the other of the two images 180° and recombine the rotated and unrotated images interferometrically.

In some aspects, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example aspect. Based on the detected interference, detector 428 can be further configured to determine a position of the center of symmetry of alignment mark or target 418 and consequently, detect a position of substrate 420. The determination can be made by, for example, an on-board processor of the detector or another processor or computing device (e.g., processor 432). According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further aspect, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can be obtained using any type of alignment sensor, for example, a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some aspects, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some aspects, beam analyzer 430 can be directly integrated into inspection apparatus 400, or connected via fiber optics of several types: polarization preserving single mode, multimode, or imaging, according to other aspects.

In some aspects, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some aspects, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some aspects, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some aspects, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some aspects, a second beam analyzer 430′ can be configured to receive and determine an optical state of diffracted radiation sub-beam 429, as shown in FIG. 4B. The optical state can be a measure of beam wavelength, polarization, or beam profile. Second beam analyzer 430′ can be identical to beam analyzer 430. Alternatively, second beam analyzer 430′ can be configured to perform one or more of the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some aspects, second beam analyzer 430′ can be directly integrated into inspection apparatus 400, or it can be connected via fiber optics of several types: polarization preserving single mode, multimode, or imaging, according to other aspects. Alternatively, second beam analyzer 430′ and beam analyzer 430 can be combined to form a single analyzer (not shown) configured to receive and determine the optical states of both diffracted radiation sub-beams 429 and 439.

In some aspects, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some aspects, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information.

In some aspects, processor 432 can determine corrections for each mark and feed the corrections back to lithographic apparatus 100 or 100′ for correcting errors in alignment/overlay, for example, by feeding corrections into the inspection apparatus 400.

### Example Diffraction Order Characterization Using a Multimode Optical Fiber

Trends in lithographic manufacture of ICs indicate a desire for high accuracy of pattern transfers (e.g., lithography at sub-nanometer precision). As a consequence, the chip manufacture industry seeks more accurate metrology tools for monitoring lithographic processes.

In some aspects, inspection systems like those in FIGS. 4A and 4B can be used to align a substrate in order to accurately layer different lithographic patterns (e.g., it is desirable for a new layer to be placed, with sub-nanometer accuracy, on top of an existing layer on a substrate). However, error offsets in measured positions can arise from defects caused by a lithographic operation or even flaws in the optics of an inspection system. Error offsets can be caused by, for example, damage to alignment marks after repeated lithographic layering, asymmetry of diffraction order pairs used in a measurement (e.g., asymmetric intensity between +1 and −1 beams of diffraction radiation sub-beam 429), signal pollution from higher diffraction orders, or the like. Therefore, inspection systems can include one or more devices and methods for determining correction term(s) to account for the error offsets.

As explained previously in reference to FIGS. 4A and 4B, interference of diffraction order pairs (e.g., +1 and −1) can be exploited in order to extract a highly accurate position of an inspection target (e.g., an alignment mark). In some aspects, a correction term can be determined by measuring an asymmetry of the diffraction order pair (e.g., measuring how much the intensity of the +1 diffraction order is different from the −1 diffraction order). To accomplish this, a portion of diffracted radiation 419 can be split off (e.g., using a beam splitter) and routed to a detector, analyzer, and/or processor that can quantify the intensities of each constituent of the diffraction order pair. From the quantified intensities, a correction term for the measured position of the inspection target can be determined. However, if other irrelevant diffraction orders are mixed into diffracted radiation 419, the resulting correction term can be less accurate.

Therefore, in some aspects, contributions from extraneous diffraction orders can be accounted for. In a non-limiting example, extraneous diffraction orders can be blocked. To perform the blocking, inspection apparatus 400 can include mechatronics (not shown) at a pupil plane of inspection apparatus 400 for moving into positions so as to block diffraction orders that are undesirable. As a non-limiting example, the mechatronics blocking element be disposed in the path of diffraction radiation beam 419 (other locations can be used). However, such motorized components can be difficult to implement due to mechanical complexity, severe space limitations in inspection apparatus 400, moving parts that risk contaminating the clean lithography environment, high cost, or the like.

In some aspects, extraneous diffraction orders can be accounted for by quantifying the additional contributing diffraction orders and then subtract their contribution from the combined signal. One or more aspects of the present disclosure are directed to using a two-dimensional array detector and a multimode optical fiber to solve problems of extraneous diffraction orders while avoiding the above-noted issues when using mechatronics.

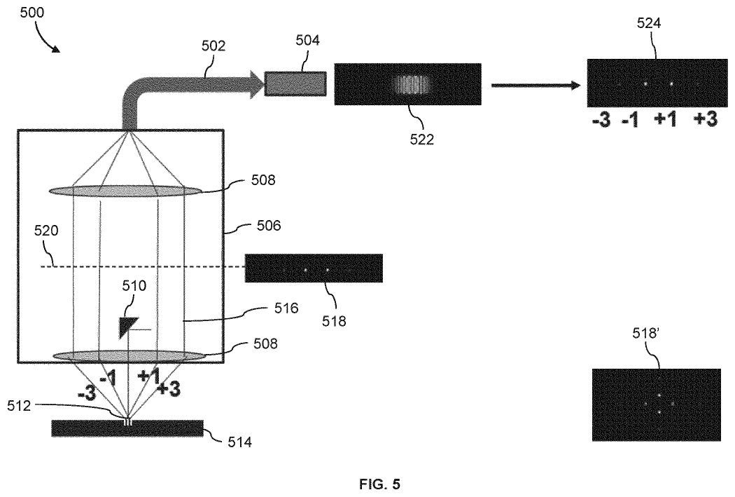

FIG. 5 shows a portion of an inspection apparatus 500, according to some aspects. In some aspects, inspection apparatus 500 can implement the capabilities, devices, and functions that were described above in reference to inspection apparatus 400 (FIGS. 4A and 4B).

In some aspects, inspection system 500 can comprise a multimode optical fiber 502, a two-dimensional detector array 504, and an optical structure 506. Optical structure 506 can be an optical objective (e.g., comprising one or more lenses 508). Inspection system 500 can also, optionally, comprise an aperture stop 510.

In some aspects, a radiation source can irradiate a target 512 on a substrate 514 to generate scattered radiation 516. Scattered radiation 516 can comprise a diffraction order pair (e.g., +1 and −1 orders). Scattered radiation 516 can also comprise an extraneous diffraction order pair (+3 and −3 orders). It is to be appreciated that the designation of +3 and −3 orders as extraneous diffraction orders is a non-limiting example. Which diffraction orders are used by a measurement and which are extraneous can vary depending on the type of information being sought by a given measurement. In some aspects, the 0th order can be blocked using aperture stop 510. Additional extraneous diffraction orders beyond +/−3 orders can be used.

In some aspects, optical structure 506 can combine a diffraction order pair(s) of scattered radiation 516 at an input side of multimode optical fiber 502. Multimode optical fiber 502 can propagate illumination from the input side to an output side. The propagation of illumination within multimode optical fiber 502 can behave according to a propagation property of multimode optical fiber 502. A non-limiting example of a propagation property can be a mixing/homogenizing effect due to internal reflections within the core of the optical fiber (other propagation properties are also envisaged, for example, dispersion). To illustrate the mixing/homogenizing effect, an image of distinguishable diffraction orders 518 is shown in FIG. 5. Distinguishable diffraction orders 518 can be present at a pupil plane 520 of inspection system 500. The diffraction orders can be mixed/homogenized by multimode fiber 502 and then output to two-dimensional detector array 504. The image detected by two-dimensional detector array 504 can be as shown via speckle pattern 522. As a result, it may be impossible, or otherwise impractical to reverse speckle pattern 522 into its diffraction order constituents using optical hardware. Scattered radiation 516 can be coherent radiation (e.g., from a laser).

However, in some aspects, speckle pattern 522 can be deconstructed into its diffraction order constituents by measuring and quantifying the propagation behavior of multimode optical fiber 502 and then applying the quantified behavior (a so called transfer function) to the output end of the fiber (i.e., the image detected at two-dimensional detector array 504). The transfer function allows the mapping of the output of multimode optical fiber 502 to the input of multimode optical fiber 502.

In some aspects, the input/output behavior of multimode optical fiber 502 can be characterized by the matrix equation 0=T. I (also “transfer function”), where T is a transmission matrix, I is a vector describing the radiation at the input of the optical fiber, and O is a vector describing the output speckle pattern 522. In other words, an input I is acted upon by the transmission matrix T to generate an output O. The transmission matrix T is a function of the material and structure of multimode optical fiber 502 and can vary based on uncertainties in the fabrication of multimode optical fiber 502. For any given construction of multimode optical fiber 502, the transmission matrix T can be ascertained via a calibration measurement (e.g., performed at factory or during the fielding of inspection system 500).

In some aspects, a well-defined image of target 512 and modal distribution can be used as input. In a first order approximation, the scattering properties of target 512 can be known to a high degree of accuracy (e.g., using a calibration grating target). The homogenized output of multimode optical fiber 502 can then be recorded. A computing device (e.g., processor 432) can analyze the input and output to determine elements of the transmission matrix T that is associated with multimode waveguide 502. The computing device can also base its analysis on the known scattering properties of the calibration grating target (e.g., angle of diffraction varies predictably according to the structure of target 512). Once the elements of the transmission matrix T are determined, inspection system 500 can be considered calibrated and can be used for inspecting targets. More details on characterizing the transfer matrix T is disclosed in WO 2022/012927A1, published on Jan. 20, 2022, and L. Amitonova and J. F. de Boer, “Endo-microscopy beyond the Abbe and Nyquist limits”, Light: Science & Applications 9:81 (2020), the contents of which are incorporated herein by reference in their entirety. It is to be appreciated that the concept of “characterizing the propagation property” of multimode optical fiber 502 can refer to the quantification of the matrix equation 0=T·I, the quantification of elements of transfer matrix T, or the like.

In some aspects, an algorithm can be programmed to reconstruct or predict the input of multimode optical fiber 502. A reconstruction of the input need not be limited to producing an image. The reconstructed information can be, for example, in digital form the radiation intensity cross-section that impinged at the input of the multimode optical fiber 502. Due to the focusing nature of optical structure 506, the surface at input of multimode optical fiber 502 can be a plane that is conjugate to pupil plane 520. Therefore, the computing device can be further configured to perform a conjugate-based transform calculation (e.g., a Fourier transform) of the radiation at the output of multimode optical fiber 502 (e.g., the output as detected by two-dimensional detector array 504). The conjugate-based transform calculation can result in reconstructed diffraction orders 524, which can be represented as in image or as intensity information (e.g., intensity values at given locations in the pupil plane).

In some aspects, distinguishable diffraction orders 518 can be distributed along a line (one dimension). However, aspects disclosed herein are not so limited. In some aspects, diffraction orders can be distributed along a plane (two dimensions), e.g., by implementing a two-dimensional diffraction structure for target 512. An example of a two-dimensional diffraction pattern is shown as distinguishable diffraction orders 518′.

In some aspects, the technique illustrated in FIG. 5 can be used to circumvent the need to use a mechanical structure to selectively block diffraction orders for the purposes of distinguishing the diffraction orders. Multimode optical fiber 502 and the reconstruction algorithm can extract the same intensity information while avoiding the issues associated with mechanized parts. As a result, it is possible to determine better correction values for the measurements performed by inspection system 500 without complicating the structure of inspection system 500 with complex mechatronics.

The functions of inspection system 500 can be expressed in the following manner. In some aspects, a radiation source can be configured to irradiate target 512 to generate scattered radiation 516. Scattered radiation 516 can comprise a diffraction order pair (e.g., a first diffracted beam (+1) and second diffracted beam (−1)). Scattered radiation 516 can further comprise another diffraction order pair (e.g., a third diffracted beam (+2, +3, or the like) and a fourth diffracted beam (−2, −3, or the like). Multimode optical fiber can be configured to receive the scattered radiation and to output a mix of the diffraction order pair based on a propagation property of multimode optical fiber 502. Optical structure 506 can be configured to combine the diffraction order pair at an input side of multimode optical fiber 502. Two-dimensional detector array 504 can be configured to receive the mix of the diffraction order pair and to generate a measurement signal corresponding to an image of the mix of the diffraction order pair. A computing device (e.g., processor 432 (FIG. 4)) can be configured to analyze the measurement signal based on the propagation property and to discriminate intensities of the first and second diffracted beams based on the analyzing.

In some aspects, inspection system 500 can be further configured to determine a value corresponding to a property of the target (e.g., an alignment position). The computing device can be further configured to determine a correction to the value based on the discriminated intensities of the diffraction order pair. The computing device can be further configured to discriminate intensities of the another diffraction order pair based on the analyzing of the measurement signal. The computing device can be further configured to perform the determining of the correction further based on the discriminated intensities of the another diffraction order pair. Inspection system 500 can be configured to propagate the diffraction order pair through pupil plane 520 such that the first diffracted beam of the diffraction order pair is disposed at a first location at pupil plane 520 and the second diffracted beam of the diffraction order pair is at a second location at pupil plane 520 different from the first location.

In some aspects, the computing device can be further configured to determine an intensity asymmetry of the first and second diffracted beams based on the analyzing of the measurement signal. The computing device can be further configured to perform a Fourier transform of data in the measurement signal and to determine image information of the diffraction order pair at pupil plane 520. The computing device can be further configured to execute an algorithm to perform the determining of intensities of the diffraction order pair. The algorithm can be configured via machine learning training using a training data set to determine the propagation property of the multimode optical fiber. More details on using machine learning can be found in Zhu, C. et al., “Image reconstruction through a multimode fiber with a simple neural network architecture,” Scientific Reports 11, 896 (2021) and Jun Zhao et al., “High-fidelity imaging through multimode fibers via deep learning,” J. Phys. Photonics 3, 015003 (2021), the contents of which are incorporated herein by reference in their entirety. Inspection system 500 can be implemented as part of a lithographic apparatus (e.g., lithographic apparatus 100 or 100′ (FIGS. 1A, 1B, and 2)).

In some aspects, enumerative adjectives (e.g., “first,” “second,” “third,” or the like) can be used in the present disclosure to distinguishing like elements without establishing an order, hierarchy, quantity, or permanent numeric assignment (unless otherwise noted). For example, the terms “first diffracted beam” and “second diffracted beam” can be used in a manner analogous to “i^{th} diffracted beam” and “j^{th} diffracted beam” so as to facilitate the distinguishing of two diffracted beams without specifying a particular order, hierarchy, quantity, or immutable numeric correspondence.

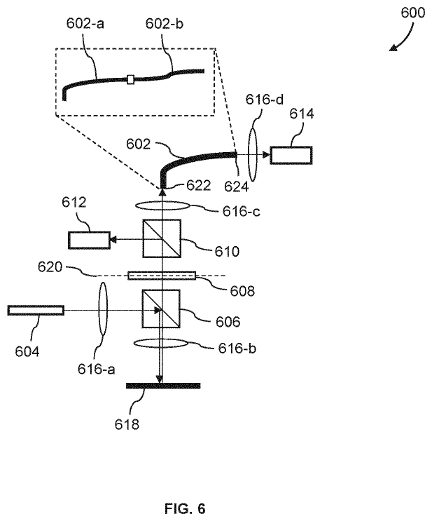

FIG. 6 shows a calibration system 600 for calibrating a multimode optical fiber 602 to be used in an inspection system, according to some aspects. In some aspects, multimode optical fiber 602 can be incorporated into inspection system 500 as multimode optical fiber 502 (FIG. 5). Calibration system 600 can be used to characterize a propagation property of multimode optical fiber 602 (e.g., determine the transfer function 0=T·I).

In some aspects, calibration system 600 can comprise a radiation source 604, a radiation deflector 606 (e.g., a beam splitter), a telescope and/or filter structure 608, a beam splitter 610, a two-dimensional detector array 612 (e.g., a first camera), a two-dimensional detector array 614 (e.g., a second camera), one or more lenses or objectives 616 (shown here explicitly are lenses 616-a through 616-d, though fewer or more can be used), and a target 618. Multimode optical fiber 602 can be implemented as a series of a two or more multimode optical fibers (as a non-limiting example, a series of multimode optical fibers 602-a and 602-b is shown). Each of lenses 616 can be a single lens or a system of lenses.

In some aspects, one or more lenses 616 can be used to focus radiation at various locations in the optical path. Lens 616-a can be disposed between radiation source 604 and radiation deflector 606. Lens 616-b can be disposed between radiation deflector 606 and target 618. Lens 616-c can be disposed between beam splitter 610 and multimode optical fiber 602. Lens 616-d can be disposed between multimode optical fiber 602 and two-dimensional detector array 614.

In some aspects, telescope and/or filter structure 608 can be used to optically align the numerous optical structures in calibration system 600. A spatial filter portion of filter structure 608 can be used to perform calibration measurements with portions of the pupil blocked (e.g., at pupil plane 620). Using the spatial filter, characterization measurements can be performed by allowing the + order through while blocking the − order (and vice versa).

In some aspects, target 618 can comprise a reticle having a plurality of diffraction structures. Each diffraction structure can generate a different configuration of diffraction order pair(s) to help characterize the propagation behavior in multimode optical fiber 602 according to the different configurations and permutations of diffraction order pair(s) (e.g., + order blocked, − order blocked, no orders blocked, or the like).

In some aspects, radiation can be sent from radiation source 604 to target 618 to generate scattered radiation having diffraction order pair(s). Beam splitter 610 can split off a portion of the scattered radiation and send the split off portion to two-dimensional detector array 612. The radiation detected at two-dimensional detector array 612 can be used to determine the state of the scattered radiation at input end 622 of multimode optical fiber 602. That is, the input portion I of the transfer function 0=T·I can be determined by analyzing the measurement signal generated by two-dimensional detector array 612.

In some aspects, the portion of scattered radiation launched into multimode optical fiber 602 can become mixed as a result of the propagation properties of multimode optical fiber 602. Output end 624 of multimode optical fiber 602 can output the mixed diffraction order pair(s). The mixed diffraction order pair(s) can be received at two-dimensional detector array 614. The radiation detected at two-dimensional detector array 614 can be used to determine the state of the scattered radiation at output end 624 of multimode optical fiber 602. That is, the output portion O of the transfer function 0=T·I can be determined by analyzing the measurement signal generated by two-dimensional detector array 614. From the measurements performed using two-dimensional detector arrays 612 and 614, elements of the transfer matrix T can be determined (e.g., using a computing device with an algorithm that analyzes the measurement signals from two-dimensional detector arrays 612 and 614). The process can be repeated until a variety of target structures and diffraction order configurations have been measured so as to determine all of the elements of the transfer matrix T or even refine the elements of transfer matrix T by averaging repeated measurements with different variations in parameters.

In some aspects, the algorithm can be a machine learning algorithm (e.g., a deep learning algorithm). The algorithm can be trained using the variety of target structures and diffraction order configurations as the training data set. Once trained, the algorithm can be executed in connection with inspection system 500 (FIG. 5) that implements multimode optical fiber 602. When inspection system 500 takes a measurement of target 512 using multimode optical fiber 602, a computing device can execute the trained algorithm so as to determine an output from multimode optical fiber 602 associated with target 518 (as captured by two-dimensional detector array 504). The algorithm can then reconstruct an input to multimode optical fiber 602 associated with target 518. Furthermore, since two-dimensional detector array 612 can receive diffraction order pair(s) in their distinguishable arrangement (separated diffracted beams), the computing device can be trained to directly reconstruct the intensity distribution of the diffracted beams at pupil plane 620 (e.g., without needing to perform a Fourier transform).

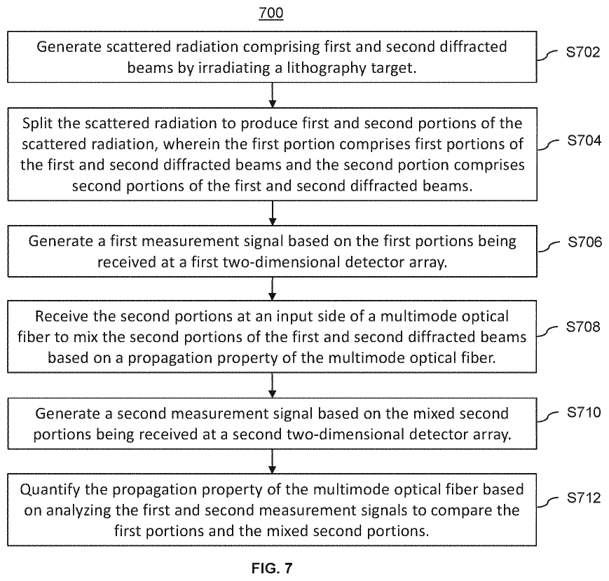

FIG. 7 shows a method 700 for characterizing and using a transfer function of multimode optical fiber 502/602 (FIGS. 5 and 6), according to some aspects. In some aspects, at step S702, scattered radiation from a lithographic target can be generated by irradiating the lithographic target (e.g., target 618 (FIG. 6)). The scattered radiation can comprise a first and second diffracted beams (e.g., +1 and −1 diffraction orders-a diffraction order pair). At step S704, the scattered radiation can be split into first and second portions (e.g., a first portion of the first diffracted beam, a first portion of the second diffracted beam, a second portion of the first diffracted beam, and a second portion of the second diffracted beam).

In some aspects, at step S706, a first measurement signal can be generated based on the first portions being received at a first two-dimensional detector array. At step S708, the second portions can be received at an input side of multimode optical fiber 602 (FIG. 6). The second portions of the first and second diffracted beams can be mixed based on a propagation property of the multimode optical fiber. At step S710, a second measurement signal can be generated based on the mixed second portions being received at a second two-dimensional detector array. At step S712, the propagation property of the multimode optical fiber can be quantified based on analyzing the first and second measurement signals to compare the first portions and the mixed second portions.

In some aspects, one or more of the operations of method 700 can be iterated using a variety of different diffraction structures, and the resulting input and output of multimode optical fiber 602 (FIG. 6) can be used as a training data set for a machine learning algorithm. The trained algorithm can be used in an inspection apparatus that uses the multimode optical fiber that was used in generating the training data set.

The method steps of FIG. 7 can be performed in any conceivable order and it is not required that all steps be performed. Moreover, the method steps of FIG. 7 described above merely reflect an example of steps and are not limiting. That is, further method steps and functions are envisaged based aspects described in reference to FIGS. 1-6.

The embodiments may further be described using the following clauses:
1. An inspection system comprising:
a radiation source configured to irradiate a target to generate scattered radiation from the target, wherein the scattered radiation comprises a diffraction order pair;
a multimode optical fiber configured to receive the scattered radiation and to output a mix of the diffraction order pair based on a propagation property of the multimode optical fiber;
an optical structure configured to combine the diffraction order pair at an input side of the multimode optical fiber;
a two-dimensional detector array configured to receive the mix of the diffraction order pair and to generate a measurement signal corresponding to the mix of the diffraction order pair; and
a computing device configured to analyze the measurement signal based on the propagation property and to discriminate intensities of the diffraction order pair based on the analyzing.
2. The inspection system of clause 1, wherein:
the inspection system is further configured to determine a value corresponding to a property of the target; and
the computing device is further configured to determine a correction to the value based on the discriminated intensities of the diffraction order pair.
3. The inspection system of clause 1, wherein:
the scattered radiation comprises another diffraction order pair; and
the computing device is further configured to:
   discriminate intensities of the another diffraction order pair based on the analyzing; and
   perform the determining of the correction further based on the discriminated intensities of the another diffraction order pair.
4. The inspection system of clause 1, wherein the inspection system is configured to propagate the diffraction order pair through a pupil plane of the inspection system such that a first diffracted beam of the diffraction order pair is disposed at a first location at the pupil plane and a second diffracted beam of the diffraction order pair is at a second location at the pupil plane different from the first location.
5. The inspection system of clause 4, wherein the computing device is further configured to determine an intensity asymmetry of the first and second diffracted beams based on the analyzing.
6. The inspection system of clause 4, wherein the computing device is further configured to perform a Fourier transform of data in the measurement signal and to determine image information of the diffraction order pair at the pupil plane.
7. The inspection system of clause 1, wherein the computing device is further configured to execute an algorithm to perform the determining of intensities of the diffraction order pair, the algorithm having been configured via machine learning training using a training data set to determine the propagation property of the multimode optical fiber.
8. A lithographic apparatus comprising:
an illumination system configured to illuminate a pattern of a patterning device;
a projection system configured to project an image of the pattern onto a substrate; and
an inspection system comprising:
   a radiation source configured to irradiate a target on the substrate to generate scattered radiation from the target, wherein the scattered radiation comprises a diffraction order pair;
   a multimode optical fiber configured to receive the scattered radiation and to output a mix of the diffraction order pair based on a propagation property of the multimode optical fiber;
   an optical structure configured to combine the diffraction order pair at an input side of the multimode optical fiber;
   a two-dimensional detector array configured to receive the mix of the diffraction order pair and to generate a measurement signal corresponding to the mix of the diffraction order pair; and
   a computing device configured to analyze the measurement signal based on the propagation property and to discriminate intensities of the diffraction order pair based on the analyzing.
9. The inspection system of clause 1, wherein:
the inspection system is further configured to determine a value corresponding to a property of the target; and
the computing device is further configured to determine a correction to the value based on the discriminated intensities of the diffraction order pair.
10. The lithographic apparatus of clause 8, wherein:
the scattered radiation comprises another diffraction order pair; and
the computing device is further configured to:
   discriminate intensities of the another diffraction order pair based on the analyzing; and
   perform the determining of the correction further based on the discriminated intensities of the another diffraction order pair.
11. The lithographic apparatus of clause 8, wherein the inspection system is configured to propagate the diffraction order pair through a pupil plane of the inspection system such that a first diffracted beam of the diffraction order pair is disposed at a first location at the pupil plane and a second diffracted beam of the diffraction order pair is at a second location at the pupil plane different from the first location.
12. The lithographic apparatus of clause 11, wherein the computing device is further configured to determine an intensity asymmetry of the first and second diffracted beams based on the analyzing.
13. The lithographic apparatus of clause 11, wherein the computing device is further configured to perform a Fourier transform of data in the measurement signal and to determine image information of the diffraction order pair at the pupil plane.
14. The lithographic apparatus of clause 8, wherein the computing device is further configured to execute an algorithm to perform the determining of intensities of the diffraction order pair, the algorithm having been configured via machine learning training using a training data set to determine the propagation property of the multimode optical fiber.
15. A method comprising:
generating scattered radiation comprising first and second diffracted beams by irradiating a lithography target;
splitting the scattered radiation to produce a first portion of the first diffracted beam, a first portion of the second diffracted beam, a second portion of the first diffracted beam, and a second portion of the second diffracted beam;
generating a first measurement signal based on the first portions being received at a first two-dimensional detector array;
receiving the second portions at an input side of a multimode optical fiber to mix the second portions of the first and second diffracted beams based on a propagation property of the multimode optical fiber;
generating a second measurement signal based on the mixed second portions being received at a second two-dimensional detector array; and
quantifying the propagation property of the multimode optical fiber based on analyzing the first and second measurement signals to compare the first portions and the mixed second portions.
16. The method of clause 15, wherein the quantifying of the propagation property comprises determining a transfer function that corresponds to a relationship between an input and an output of the multimode optical fiber.
17. The method of clause 15, wherein the lithographic target comprises a plurality of diffraction structures and the method further comprises generating a plurality of diffraction order pairs corresponding to the plurality of diffraction order structures.
18. The method of clause 17, wherein the quantifying of the propagation property comprises analyzing the plurality of diffraction order pairs using machine learning algorithm.
19. The method of clause 18, further comprising determining an intensity for each of the first and second diffracted beams based on the quantifying and using the machine learning algorithm.
20. The method of clause 18, further comprising generating data of an image reconstruction of the first and second diffracted beams, wherein the first and second diffracted beams are disposed at different locations in the image reconstruction.

The terms “radiation,” “beam,” “light,” “illumination,” or the like can be used herein to refer to one or more types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. It should be appreciated that radiation having a wavelength in the range of, for example, 5-20 nm relates to radiation with a certain wavelength band, of which at least part is in the range of 5-20 nm.

Although some aspects of the present disclosure are described in the context of lithographic apparatuses in the manufacture of ICs, it should be understood that lithographic apparatuses described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described in the context of optical lithography, it should be understood that aspects of the present disclosure are not limited to optical lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. An inspection system comprising:
a multimode optical fiber configured to receive scattered radiation from a target, the scattered radiation comprising a diffraction order pair, and to output a mix of the diffraction order pair based on a propagation property of the multimode optical fiber;
an optical structure configured to combine the diffraction order pair at an input side of the multimode optical fiber;
a two-dimensional detector array configured to receive the mix of the diffraction order pair and to generate a measurement signal corresponding to the mix of the diffraction order pair; and
a computing device configured to analyze the measurement signal based on the propagation property and to discriminate intensities of the diffraction order pair based on the analysis of the measurement signal.

2. The inspection system of claim 1, wherein:
the inspection system is further configured to determine a value corresponding to a property of the target; and
the computing device is further configured to determine a correction to the value based on the discriminated intensities of the diffraction order pair.

3. The inspection system of claim 2, wherein:
the scattered radiation comprises another diffraction order pair; and
the computing device is further configured to:
discriminate intensities of the another diffraction order pair based on the analysis of the measurement signal; and
determine the correction to the value based further on the discriminated intensities of the another diffraction order pair.

4. The inspection system of claim 1, wherein the inspection system is configured to propagate the diffraction order pair through a pupil plane of the inspection system such that a first diffracted beam of the diffraction order pair is disposed at a first location at the pupil plane and a second diffracted beam of the diffraction order pair is at a second location at the pupil plane different from the first location.

5. The inspection system of claim 4, wherein the computing device is further configured to determine an intensity asymmetry of the first and second diffracted beams based on the analysis of the measurement signal.

6. The inspection system of claim 4, wherein the computing device is further configured to perform a Fourier transform of data in the measurement signal and to determine image information of the diffraction order pair at the pupil plane.

7. The inspection system of claim 1, wherein the computing device is further configured to execute an algorithm to determine intensities of the diffraction order pair, the algorithm having been configured via machine learning training using a training data set to determine the propagation property of the multimode optical fiber.

8. A lithographic apparatus comprising:
an illumination system configured to illuminate a pattern of a patterning device;
a projection system configured to project an image of the pattern onto a substrate; and
an inspection system comprising:
a multimode optical fiber configured to receive the scattered radiation from a target, the scattered radiation comprising a diffraction order pair, and to output a mix of the diffraction order pair based on a propagation property of the multimode optical fiber;
an optical structure configured to combine the diffraction order pair at an input side of the multimode optical fiber;
a two-dimensional detector array configured to receive the mix of the diffraction order pair and to generate a measurement signal corresponding to the mix of the diffraction order pair; and
a computing device configured to analyze the measurement signal based on the propagation property and to discriminate intensities of the diffraction order pair based on the analysis of the measurement signal.

9. The lithographic apparatus of claim 8, wherein:
the inspection system is further configured to determine a value corresponding to a property of the target; and
the computing device is further configured to determine a correction to the value based on the discriminated intensities of the diffraction order pair.

10. The lithographic apparatus of claim 9, wherein:
the scattered radiation comprises another diffraction order pair; and
the computing device is further configured to:
discriminate intensities of the another diffraction order pair based on the analysis of the measurement signal; and
determine the correction to the value based further on the discriminated intensities of the another diffraction order pair.

11. The lithographic apparatus of claim 8, wherein the inspection system is configured to propagate the diffraction order pair through a pupil plane of the inspection system such that a first diffracted beam of the diffraction order pair is disposed at a first location at the pupil plane and a second diffracted beam of the diffraction order pair is at a second location at the pupil plane different from the first location.

12. The lithographic apparatus of claim 11, wherein the computing device is further configured to determine an intensity asymmetry of the first and second diffracted beams based on the analysis of the measurement signal.

13. The lithographic apparatus of claim 11, wherein the computing device is further configured to perform a Fourier transform of data in the measurement signal and to determine image information of the diffraction order pair at the pupil plane.

14. The lithographic apparatus of claim 8, wherein the computing device is further configured to execute an algorithm to determine intensities of the diffraction order pair, the algorithm having been configured via machine learning training using a training data set to determine the propagation property of the multimode optical fiber.

15. A method comprising:
generating scattered radiation comprising first and second diffracted beams by irradiating a lithography target;
splitting the scattered radiation to produce a first portion of the first diffracted beam, a first portion of the second diffracted beam, a second portion of the first diffracted beam, and a second portion of the second diffracted beam;
generating a first measurement signal based on the first portions being received at a first two-dimensional detector array;
receiving the second portions at an input side of a multimode optical fiber to mix the second portions of the first and second diffracted beams based on a propagation property of the multimode optical fiber;
generating a second measurement signal based on the mixed second portions being received at a second two-dimensional detector array; and
quantifying the propagation property of the multimode optical fiber based on analyzing the first and second measurement signals to compare the first portions and the mixed second portions.

16. The method of claim 15, wherein the quantifying of the propagation property comprises determining a transfer function that corresponds to a relationship between an input and an output of the multimode optical fiber.

17. The method of claim 15, wherein the lithographic target comprises a plurality of diffraction structures and the method further comprises generating a plurality of diffraction order pairs corresponding to the plurality of diffraction order structures.

18. The method of claim 17, wherein the quantifying of the propagation property comprises analyzing the plurality of diffraction order pairs using a machine learning algorithm.

19. The method of claim 18, further comprising determining an intensity for each of the first and second diffracted beams based on the quantifying and using the machine learning algorithm.

20. The method of claim 18, further comprising generating data of an image reconstruction of the first and second diffracted beams, wherein the first and second diffracted beams are disposed at different locations in the image reconstruction.
